(19) United States
(12) Patent Application Publication
(10) Pub. No.: US 2010/0320678 A1
(43) Pub. Date: Dec. 23, 2010

(54) PAPER SHEET IDENTIFYING/COUNTING APPARATUS AND PAPER SHEET IDENTIFYING/COUNTING METHOD

(75) Inventors: Masayoshi Suzuki, Kanagawa-Ken (JP); Hiroshi Murata, Kanagawa-Ken (JP); Kazuhisa Matsuda, Kanagawa-Ken (JP)

Correspondence Address: FOLEY AND LARDNER LLP;SUITE 500, 3000 K STREET NW, WASHINGTON, DC, 20007, US

(73) Assignee: BILLCON CORPORATION

(21) Appl. No.: 12/443,391

(22) PCT Filed: Jan. 30, 2009
(86) PCT No.: PCT/JP2009/051551

§ 371 Date: Mar. 27, 2009

(51) Int. Cl. B65H 7/02; G01B 7/30; G01R 33/02; B65H 1/00; G01N 21/00

(52) U.S. Cl. 271/265.01; 324/207.25; 324/244; 271/145; 356/432

(57) ABSTRACT

A bank note identifying/counting apparatus 10 comprises a hopper 15 to which paper sheets to be identified and counted are supplied, a paper sheet transport device 33 for continuously feeding out the paper sheets supplied to the hopper 15 and transporting the paper sheets one by one in a shorter direction thereof along a transport path 52, a paper sheet identifying unit 70 disposed in a mid-portion of the transport path 52 for identifying and counting the paper sheets, and one stacker 20 on which the paper sheets fed out from the transport path 52 are stacked, wherein the transport path 52 is composed of a feed-out transport path 52a to the back side of which the paper sheets from the hopper are continuously fed out, a downward linear transport path 52b succeeding to the feed-out transport path 52a, and a downstream transport path 52c extending forward from the linear transport path 52b to the stacker 20, and the transport path 52 is formed so as to provide a curved U-shape or C-shape, and the paper sheet identifying unit 70 is installed upstream of the downward linear transport path so that a magnetic sensor 66 traverses the transport path. With the above arrangement, there is be provided a small and compact paper sheet identifying/counting apparatus, which stably and continuously feeds out paper sheets without causing a transport mistake and a transport delay even to damaged paper sheets achieves low noise and good transport efficiency, and there is also provided a paper sheet identifying/counting method by using the apparatus.

### TECHNICAL FIELD

The present invention relates to a paper sheet identifying/counting apparatus and a paper sheet identifying/counting method for identifying and counting paper sheets, and more particularly, to a desktop compact paper sheet identifying/counting apparatus and a paper sheet identifying/counting method for discriminating denominations of bank notes and a bank note counting process at a high speed.

### BACKGROUND ART

Conventionally, as such type of a paper sheet identifying/counting apparatus, there is known a desktop paper sheet identifying/counting apparatus for discriminating the denominations of bank notes and performing a bank note counting process.

In the desktop paper sheet identifying/counting apparatus, a hopper is disposed in front of a top portion of a counting apparatus main body, and bank notes to be identified are supplied to and stacked on the hopper. When the identifying/counting apparatus is started, the bank notes stacked on the hopper are intermittently fed one by one by a feed-out roller. These fed bank notes are transported one by one in the shorter direction thereof through a transport path in the counting apparatus main body, subjected to a discrimination process of the denominations of the bank notes and to a truth/false discrimination process by an identifying unit disposed in a mid-portion of the transport path, and the number and the amount of the bank notes are counted.

The bank notes, whose denomination is discriminated by the bank note identifying unit and whose number is counted, are subsequently guided onto a stacker through a downstream transport path and can be taken out from the stacker.

Patent Document 1 discloses a paper sheet (bank note) identifying/counting apparatus employing an intermittent feed-out mechanism as this type of a paper sheet identifying/counting apparatus. The paper sheet identifying/counting apparatus employs the intermittent feed-out mechanism to a hopper and a friction member such as urethane rubber and the like is disposed to a part of a feed-in roller and a feed-out roller in the peripheral direction thereof so that bank notes stacked on the hopper can be intermittently fed out one by one from a lowermost one.

Patent Document 1: Japanese Unexamined Patent Application Publication No. 2001-344635

In conventional paper sheet identifying/counting apparatuses, bank notes from a hopper are intermittently fed out and transported, and moreover the intermittent feed-out depends on the transport force of a friction member such as rubber and the like partly disposed only to a portion of a feed-in roller and a feed-out roller in the peripheral direction thereof. Accordingly, the conventional paper sheet identifying/counting apparatuses are disadvantageous in that since bank notes fed out from the hopper abruptly come into contact with the friction member, the bank notes are disturbed, a slant transport specific to the intermittent feed-out mechanism occurs frequently, a transport is made unstable and is not stabilized, the bank notes are erroneously fed out and erroneously discriminated due to the slant transport and transported in an overlapped state, and a delay occurs in a transport, and the like.

Further, in the conventional paper sheet identifying/counting apparatuses, pulse boards of disk-shaped encoders are disposed to respective motor shafts of a feed-out drive motor and a transport drive motor acting as drive sources for identifying and counting bank notes so that the pulse boards are exposed from the motor shafts. A light emitting element and a light receiving element are disposed to slits of the pulse boards of the encoders in confrontation with each other, and the amounts of rotation (the number of revolutions and a rotation angles) of both the drive motors are detected by detecting the light passing through the slits by these light emitting/receiving elements (optical elements).

However, in the conventional paper sheet identifying/counting apparatuses, the pulse boards of the encoders are disposed to the motor shafts of both the drive motors disposed to a lower portion of a counting apparatus main body. The pulse boards and the respective optical elements constituting the encoders are disposed to the lower portion of the counting apparatus main body and exposed to the periphery of the lower portion of the main body. Further, dusts such as paper powders and the like of bank notes float and scatter in the counting apparatus main body and are deposited therein. Accordingly, there is a problem in that the optical axes of the optical elements are shut off by the dusts, further amounts of light of them is reduced, and the dusts are deposited on the slits of the pulse boards to thereby make a generated signal unstable.

Further, although the conventional paper sheet identifying/counting apparatus has an exclusion pocket in addition to the stacker so that counterfeit notes and the like are excluded by the exclusion pocket, there is a problem of a slant transport specific to an intermittent feed-out. When the slant transport occurs, a problem of deterioration of reliability arise in that a true bank note is judged as a counterfeit note and excluded to the exclusion pocket, and when banknotes having mixed denominations are counted, accuracy of count is lacked and reliability is lowered.

Furthermore, in the two-pocket structure having the exclusion pocket in addition to the stacker, since a branch mechanism is provided therebetween, a transport path is made complex, a handling operation is complex, and it is difficult to eliminate a jam phenomenon.

### DISCLOSURE OF THE INVENTION

An object of the present invention, which was conceived in view of the above circumstances, is to provide a small and compact paper sheet identifying/counting apparatus and method, which can stably and continuously feed out paper sheets, is unlike to make a transport mistake and a transport delay even to damaged paper sheets, and achieves low noise and a good transport efficiency.

Another object of the present invention is to provide a highly reliable paper sheet identifying/counting apparatus and method which simplifies a transport path structure of paper sheets and easily eliminates a jam phenomenon as well as stably and accurately detects, identifies and counts paper sheets.

A still another object of the present invention is to provide a paper sheet identifying/counting apparatus and method in which a magnetic sensor is disposed in a linear transport path before a speed is increased so that a magnetic pattern before the speed is increased and a magnetic pattern after the speed is increased can be obtained according to a reference of a paper sheet transport length.

In order to achieve the above-mentioned objects, the present invention provides, in one aspect, as recited in claim 1, a paper sheet identifying/counting apparatus comprising:

a hopper to which paper sheets to be identified and counted are supplied;

a paper sheet transport device for continuously feeding out the paper sheets supplied to the hopper and transporting the paper sheets one by one in a shorter direction thereof along a transport path;

a paper sheet identifying unit disposed in a mid-portion of the transport path for identifying and counting the paper sheets; and one stacker on which the paper sheets fed out from the transport path are stacked,

wherein the transport path is composed of a feed-out transport path to a back side of which the paper sheets from the hopper are continuously fed out, a downward linear transport path succeeding to the feed-out transport path, and a downstream transport path extending forward from the linear transport path to the stacker, and the transport path is formed so as to provide a curved U-shape or C-shape, and

the paper sheet identifying unit is installed upstream of the downward linear transport path so that a magnetic sensor traverses the transport path.

Furthermore, in order to achieve the above-mentioned objects, the present invention provides, in another aspect, as recited in claim 6, a paper sheet identifying/counting method, comprising the steps of:

continuously feeding out paper sheets stacked on a hopper to a feed-out transport path at a feed-out speed of 1000 sheets, 1200 sheets, or more per minute;

guiding the fed-out paper sheets to a downward linear transport path;

identifying and counting the paper sheets, and discriminating whether the paper sheets are true or false by a paper sheet identifying unit while the paper sheets pass through the linear transport path;

guiding the paper sheets identified and counted by a paper sheet identifying unit to a downstream transport path; and

feeding out the paper sheets from the downstream transport path to a stacker and stacked on the stacker.

In the paper sheet identifying/counting apparatus and the paper sheet identifying/counting method according to the present invention, paper sheets are not transported in a slant state and can be stably and continuously feed out, a transport mistake and a transport delay are unlike to be caused even to damaged paper sheets, low noise and a good transport efficiency are achieved, and paper sheets are identified and counted by the small and compact identifying/counting apparatus with high reliability.

Further, the paper sheet identifying/counting apparatus can form a paper sheet transport path in a C-shape or a U-shape and increase the length thereof even if it is a small and compact apparatus and can stably and accurately identify and count paper sheets at a high speed by simplifying a transport path structure.

### BRIEF DESCRIPTION OF THE DRAWINGS

FIG. 1 is an overall perspective view showing an embodiment of a bank note identifying/counting apparatus as a paper sheet identifying/counting apparatus according to the present invention.

FIG. 2 is a perspective view of the bank note identifying/counting apparatus as viewed from a back surface side thereof.

FIG. 3 is a left side elevational view showing a machine room in a state that a left side cover of the bank note identifying/counting apparatus is removed.

FIG. 4 is a right side elevational view showing a control room in a state that the left side cover and a judge substrate of the bank note identifying/counting apparatus are removed.

FIG. 5 is a sectional view showing a transport path structure of a paper sheet (bank note) transport device formed in the bank note identifying/counting apparatus.

FIG. 6 is an exploded perspective showing a transport portion disposed in the bank note identifying/counting apparatus.

FIG. 7 is a side elevational view showing various types of sensors assembled to the bank note identifying/counting apparatus and a transport path structure of bank notes.

FIG. 8 is a view showing a state in which the bank note identifying/counting apparatus is opened on the back surface side thereof.

FIG. 9 is an installation view showing an attachment state of hermetically-sealed rotary encoders disposed to the bank note identifying/counting apparatus.

FIG. 10 is a view showing a example of an attachment structure of a magnetic sensor assembled to the bank note identifying/counting apparatus.

FIG. 11A is a front elevational view showing an installation state of a density sensor and an edge count sensor installed on a downstream side of the magnetic sensor, and FIG. 11B is a side sectional view of the edge count sensor.

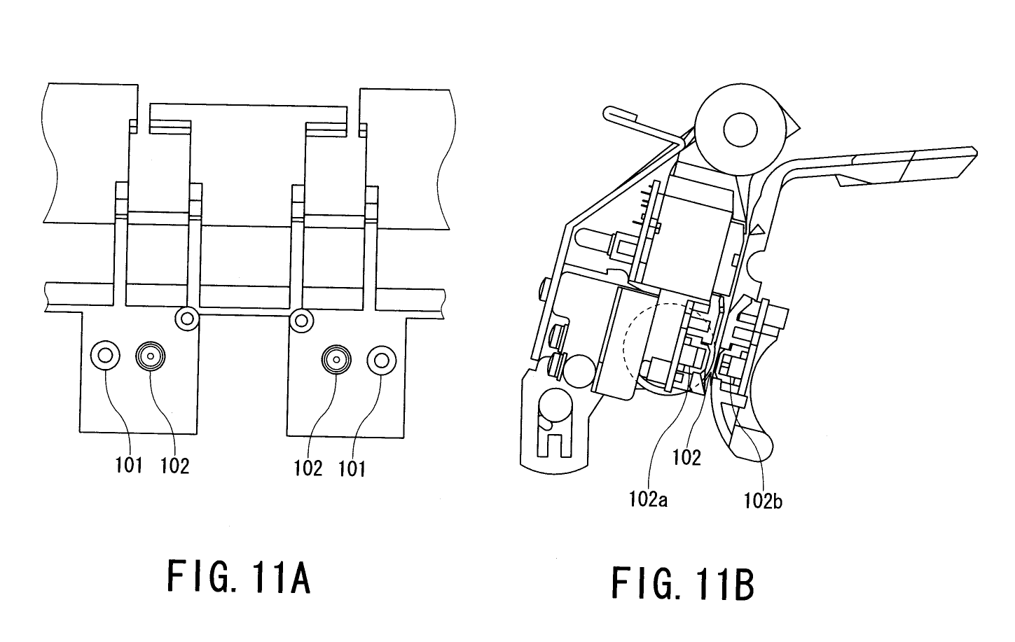

### EXPLANATION OF REFERENCE NUMERALS

10 bank note identifying/counting apparatus
11 the counting apparatus main body
12 top cover
13a right side cover
13b left side cover
15 hopper
16 operation panel
17 display panel
18 operation button
20 stacker
21 stacker vane
25 hopper guide
26 rear cover
26a rear upper cover
26b rear lower cover
32 gap adjustment dial
33 paper sheet (bank note) transport device
35 main body plate (partition blade: left)
36 main body plate (partition blade: right)
41 paper sheet feed-out mechanism
42 feed-out power transmission mechanism
43 paper sheet transportation drive system
44 transport system drive power transmission mechanism
45 feed-out drive motor
46 transport drive motor
51 feed-in mechanism
52 transport path
53 feed-in roller
54 feed-out roller (drum)
55, 56 rotary encoder
58 stop roller
62 platen roller
66 magnetic sensor
70 paper sheet (bank note) identifying unit
73 rear guide
76 feed-out side drive pulley
81 feed-out side transport path
91 right transport path
92 roller shaft
93 left transport path
95, 96 drive system
101 density sensor
102 edge count sensor

### BEST MODE FOR CARRYING OUT THE INVENTION

An embodiment of the present invention will be explained referring to the accompanying drawings.

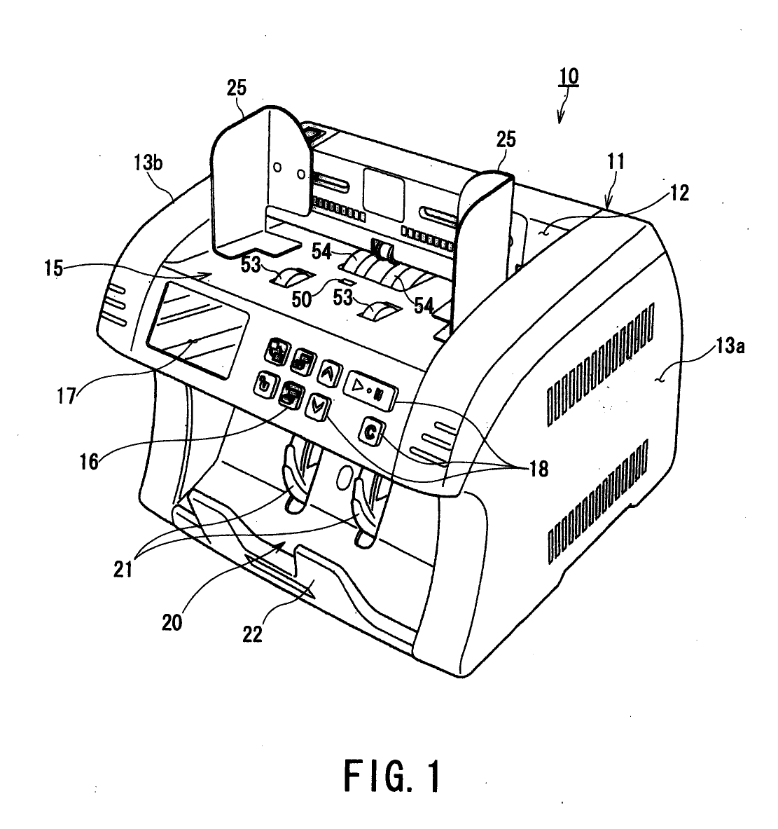

FIG. 1 is an overall perspective view showing an example a paper sheet identifying/counting apparatus according to the present invention. The paper sheet identifying/counting apparatus is a desktop compact bank note identifying/counting apparatus for performing a process of identifying, for example, bank notes as paper sheets at a high speed of 1000 sheets, 1200 sheets or more per minute and counting them.

The bank note identifying/counting apparatus 10 is formed in a modified box-shape in its entirety, the top portion and both the side portions of a counting apparatus main body 11 are covered with a resin top cover 12 and resin right and left side covers 13a, 13b, respectively, and the back surface side of the counting apparatus main body 11 is covered with a rear cover 26. The top cover 12 extends forward from the back surface side, whereas the right and left side covers 13a, 13b continue to the front end of the top cover 12. The front edges of the side covers 13a, 13b are formed to smooth concave curved surfaces, and the bank note identifying/counting apparatus 10 is formed in an S-shape from the top portion to the front surface thereof when viewed from a side surface.

The bank note identifying/counting apparatus 10 has a hopper 15 which is disposed near to the front side of the top portion of the counting apparatus main body 11 and to which bank notes 14 to be counted as paper sheets are supplied. Whereas, the bank note identifying/counting apparatus 10 is provided with an operation panel 16 and a display panel 17 such as LCD and the like of the bank note identifying/counting apparatus 10 which are disposed on the front surface side of the top cover 12 integrally therewith, and the display panel 17 full graphically displays an identified/counted state of bank notes. Further, the display panel 17 displays the number of counted bank notes, a set value of the number of counted bank notes, and an error. A plurality of, for example, eight operation buttons as operation keys 18 are disposed on the operation panel 16. The operation buttons 18 select an identifying/counting function of various bank notes and set various counting modes, and bank notes are identified and counted in correspondence to the counting modes by operating these operation buttons 18.

Further, a stacker 20 is disposed to a lower portion of the front surface side of the bank note identifying/counting apparatus 10 to stack identified and counted bank notes. The bank notes identified and counted by the bank note identifying/counting apparatus 10 are fed out one by one by a stacker vane (vane wheel) 21, and the counted bank notes are supported by a stacker support 22 and accommodated on the stacker 20.

In contrast, the hopper 15 of the bank note identifying/counting apparatus 10 is used to place the bank notes 14 to be counted thereon, and a pair of left and right hopper guides 25, 25 are slidably disposed to the hopper 15 so that they are free to advance and retreat in order to stack the bank notes 14 in an aligned state. The hopper guides 25, 25 are guides for aligning the bank notes to be counted by moving them toward the centers thereof so that the right and left positions of the bank notes are adjusted in accordance with the longer direction sizes thereof.

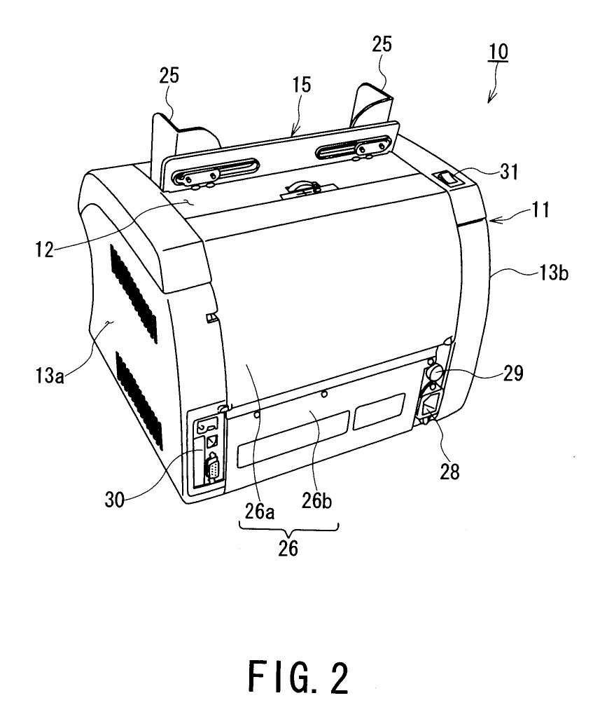

Further, the back surface side of the bank note identifying/counting apparatus 10 is covered with a rear cover 26 composed of a rear upper cover 26a and a rear lower cover 26b as shown in FIG. 2. The rear upper cover 26a is openably and closably hinge coupled with the rear lower cover 26b. The rear upper cover 26a is opened to perform a necessary job when a paper sheet is jammed in the bank note identifying/counting apparatus 10 (jam phenomenon) and when cleaning and maintenance of the inside of the apparatus are performed.

A power supply connector 28 of a main power supply, to which a power supply cord is connected, and a fuse 29 of the main power supply are disposed to, for example, one side of the rear cover 26, and a communication port 30 such as a USB port and the like is disposed to the other side thereof. The bank note identifying/counting apparatus 10 can be connected to communication equipment such as a personal computer and the like through the communication port 30. Note that reference numeral 31 denotes a power supply switch for turning ON and OFF the bank note identifying/counting apparatus 10, reference numeral 32 denotes a gap adjustment dial. The gap adjustment dial 32 adjusts a gap in accordance with the thickness and the state of bank notes to be counted so that the bank notes on the hopper 15 can be smoothly guided into the counting apparatus main body 11.

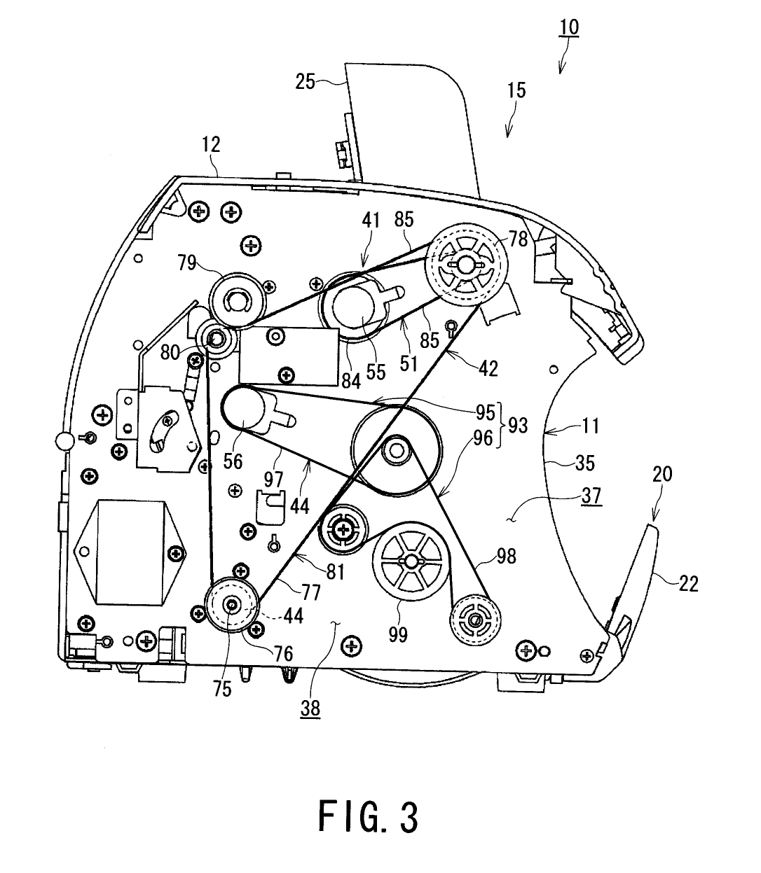

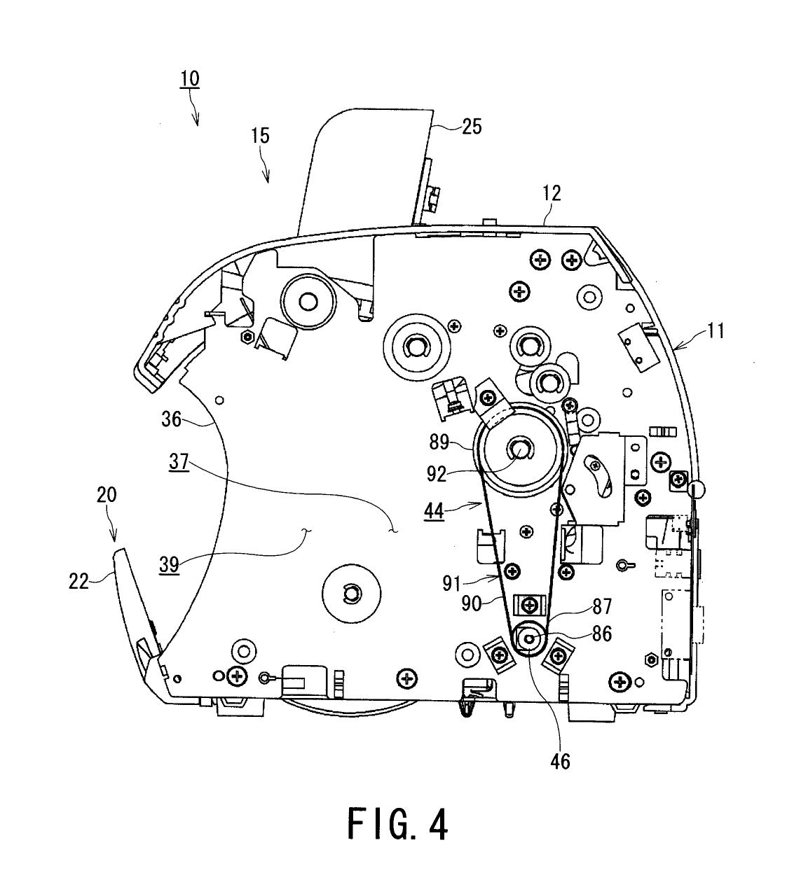

As shown in FIGS. 3 and 4, the counting apparatus main body 11 of the bank note identifying/counting apparatus 10 has right and left main body plates 35, 36, and a paper sheet transport device 33 is interposed between the main body plates 35, 36 in the bank note identifying/counting apparatus 10. The bank note identifying/counting apparatus 10 is partitioned to a central main space 37 and to right and left side spaces 38, 39 by the right and left main body plates 35, 36. The side spaces 38, 39 are formed between the main body plates 35, 36 and the right and left side covers 13a, 13b. One of the side spaces 31a, 31b (left side) is arranged as a power transmission machine room, and the other thereof is arranged as a control room for mainly controlling the operation of the paper sheet transport device 33 disposed to the bank note identifying/counting apparatus 10.

As shown in FIG. 3, a feed-out power transmission mechanism 42, which drives a paper sheet feed-out drive system 41, and a transport system drive power transmission mechanism 44, which drives a paper sheet transportation drive system 43, are accommodated in, for example, the left side space 38 constituting the machine room.

Further, as shown in FIG. 4, a part of the system drive power transmission mechanism 44 is accommodated in the right side space 39 constituting the control room as well as a control substrate (not shown) is three-dimensionally disposed to the right side space 39 to control the operation of the bank note identifying/counting apparatus 10.

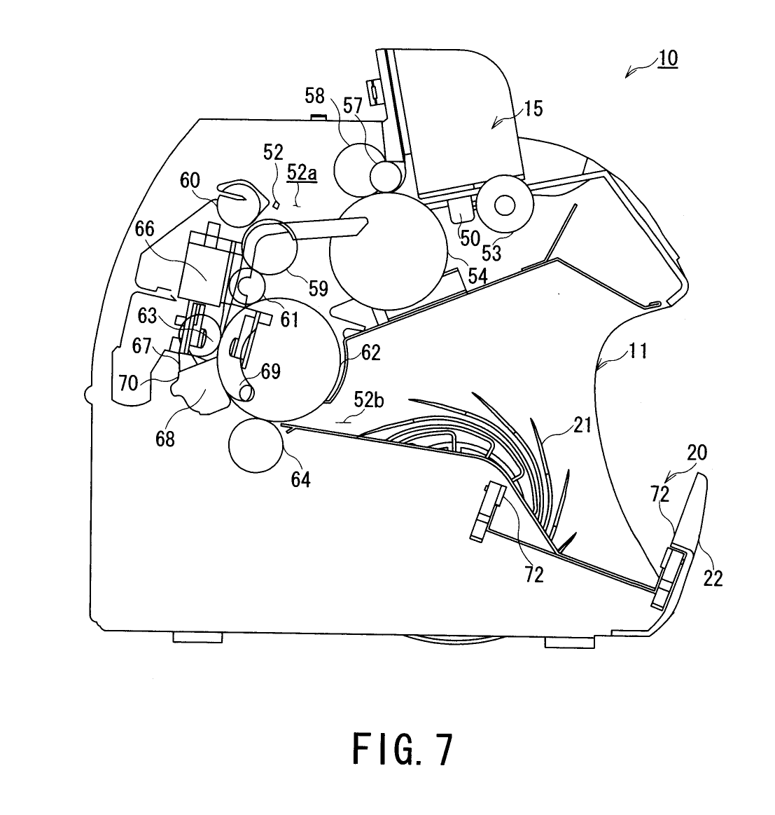

As shown in FIG. 7, the bank note identifying/counting apparatus 10 has two drive sources linearly disposed at the center of the bottom of the counting apparatus main body 11. The drive sources are a feed-out drive motor 45 and a transport drive motor 46. Although both the drive motors 45, 46 need not be driven by counting timing, motors of the same type are employed so that they are rotated at approximately the same revolution speed. Both the drive motors 45, 46 are covered with and sealed by cylindrical magnetic seals 47, and the feed-out drive motor 45 is provided with a brake device (not shown) such as an electromagnetic brake, a mechanical brake and the like for abruptly stopping the revolution of the motor.

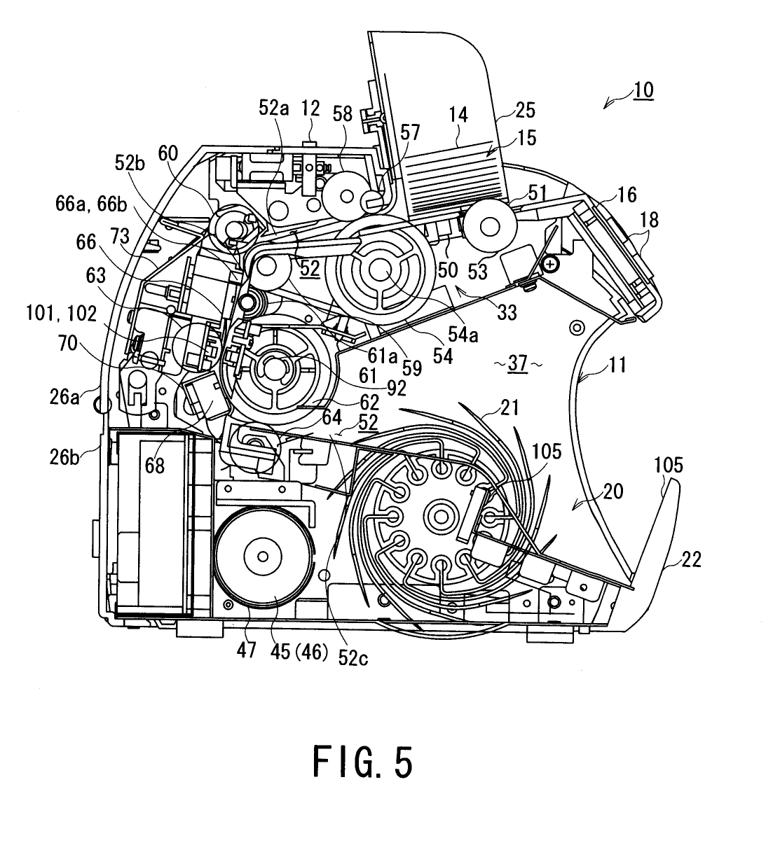

In contrast, as shown in FIG. 5, in the counting apparatus main body 11 of the bank note identifying/counting apparatus 10, a reflection type hopper sensor 50 is disposed on the bottom of the hopper 15, and whether or not the bank notes 14 are stacked on the hopper 15 is detected by the hopper sensor 50. The bank notes 14 stacked on the hopper 15 are fed into a transport path 52 one by one, which is curved in a U-shape or a C-shape, by a continuous feed-in mechanism 51. For example, a pair of feed-in rollers 53 are disposed on the bottom of the hopper 15 as the feed-in mechanism 51. A friction member composed of urethane rubber and the like is trained around the outer peripheral surface of each of the feed-in rollers 53 so that a lowermost bank note is continuously fed toward a feed-out transport path 52a on the back surface side by the revolution of the feed-in roller 53.

The lowermost bank note, which is fed in from the feed-in rollers 53 in a shorter direction, is fed out by a feed-out roller as a feed-out mechanism or a drum 54. The feed-out roller 54 and the feed-in rollers 53 are driven in rotation by counting timing by a timing belt 55 of the feed-in mechanism 51 so that they are driven at a predetermined surface speed ratio. A friction member of urethane rubber and the like is entirely trained around the outer peripheral surface of the feed-out roller 54 to secure the stable transport of bank notes.

The feed-out roller 54 and the feed-in rollers 53 are arranged to perform a uniform motion at a necessary surface speed or at a necessary surface speed ratio. A hermetically-sealed rotary encoder 55 is disposed to a roller shaft 54a of the feed-out roller 54. The number of revolutions (revolution speed) and a revolution angle of the feed-out roller 54 are measured by the rotary encoder 55 so that the feed-out speed of a bank note is directly measured. The stacked bank notes 14 are sequentially fed in and fed out from the hopper 15 by the feed-in rollers 53 of the feed-in mechanism 51 in cooperation with the feed-out roller 54.

An auxiliary roller 57 as a friction roller and a stop roller 58 as an overlapped feed prevention stop member are disposed to the feed-out roller 54. Among them, the stop roller 58 is a roller of urethane rubber and the like having a large friction force and supported by a stop roller shaft through a one way crutch, is not rotated in a feed-out direction, and is free to rotate in a counter feed-out direction. A jammed bank note can be taken out by a feed-out unit without damaging it. Further, when the transport of a bank note is finished, the stop roller 58 is slightly rotated making use of the reaction force of a feed-out force so that it is uniformly worn naturally. Bank notes can be prevented from being fed in an overlapped state by the stop roller 58. The gap between the stop roller 58 and the feed-out roller 54 is adjusted through an advance/retreat mechanism (not shown) by rotationally scanning a gap adjustment dial 32.

The bank note, which is fed out to the transport path 52 by the feed-out roller 54, is fed out to the transport path 52a while being prevented from the overlapped feed by the stop roller 58 and guided toward an intermediate roller 59 through the feed-out transport path 52a. The fed-out bank note is clamped between the intermediate roller 59 and an intermediate pinch roller 60 and applied with transport force by them and guided to a downward linear transport path 52b formed along the counting apparatus main body 11. The intermediate pinch roller 60 is elastically pressed to the intermediate roller 59 side by an elastic member such as a spring and the like so that the transport force is applied to the bank note.

The downward linear transport path 52b, the direction of which is changed from the intermediate roller 59 and which travels downward, is guided to a platen roller 62 passing through a flock roller 61 having a brush 61a. The platen roller 62 is a speed increased roller having the same diameter as that of the feed-out roller 54 and is rotated at, for example, a surface speed about 1.5 times to 2 times larger than that of the feed-out roller 54.

As an example, the platen roller 62 is rotated at a surface speed about 1.6 times that of the feed-out roller 54. A pinch roller 63 is spring-urged and abutted against the platen roller 62 to apply transport force to a bank note. A hermetically-sealed rotary encoder 56 is also disposed to an end of a roller shaft 92 of the platen roller 62 to directly measure the surface speed (the number of revolutions and a rotation angle) of the platen roller.

After the direction of the bank note whose speed is increased by the speed increasing roller (platen roller) 62 and the pinch roller 63 is clamped by the platen roller 62 and a roller bearing 64, the bank note is guided to an oblique downward downstream side transport path 52c toward the stacker 20.

At the time, the feed-out roller 54, the intermediate roller 59, and the flock roller 61 constitute a drive side of the paper sheet feed-out drive system 41 which constitutes the paper sheet transport device 33, and further the platen roller 62 and the stacker vane 21 constitute a drive side of the paper sheet transportation drive system 43. The feed-out roller 54, the intermediate roller 59, and the flock roller 61, which constitute the drive side, and the platen (speed increasing) roller 62 are concentratedly positioned inside of the U-shaped or C-shaped transport path 52 taking it into consideration that when a jam phenomenon occurs to paper sheets such as bank notes and the like, it can be smoothly eliminated. Since the length of a bank note transport path can be increased by forming the transport path 52 in the U-shape or the C-shape, even if a paper sheet (bank note) identifying unit 70 is disposed to a mid-portion of the bank note transport path, a bank note can be fed at a high speed of, for example, 1000 sheets, 1200 sheets or more per minute.

The U-shaped or C-shaped transport path 52 is divided into the feed-out transport path 52a, the downward linear transport path 52b, and the forward oblique downward downstream side transport path 52c. The bank note identifying/counting apparatus 10 is further roughly divided into the feed-out transport path 52 on the upstream side of the platen roller 62 before a speed is increased and the transport path 52 on the downstream side of the platen roller 62 after the speed is increased. The downward linear transport path 52b is a transport region in which a bank note is changed from the state before its speed is increased to the state after its speed is increased. When the bank note is clamped by the platen roller 62 and the pinch roller 63, the speed of the bank note is increased when it passes through the linear transport path 52b. The downward linear transport path 52b is a region in which the transport speed of a bank note is changed, and a magnetic sensor 66 is disposed upstream of the linear transport path 52b. A UV sensor 67, an image sensor 68, and count sensors 69 are interposed between the pinch roller 63 and the roller bearing 64 in the vicinity of an inlet side of the downstream side transport path 52c after the speed is increased from the downstream side of the downward linear transport path 52b to the downstream side transport path 52c on the speed increased side.

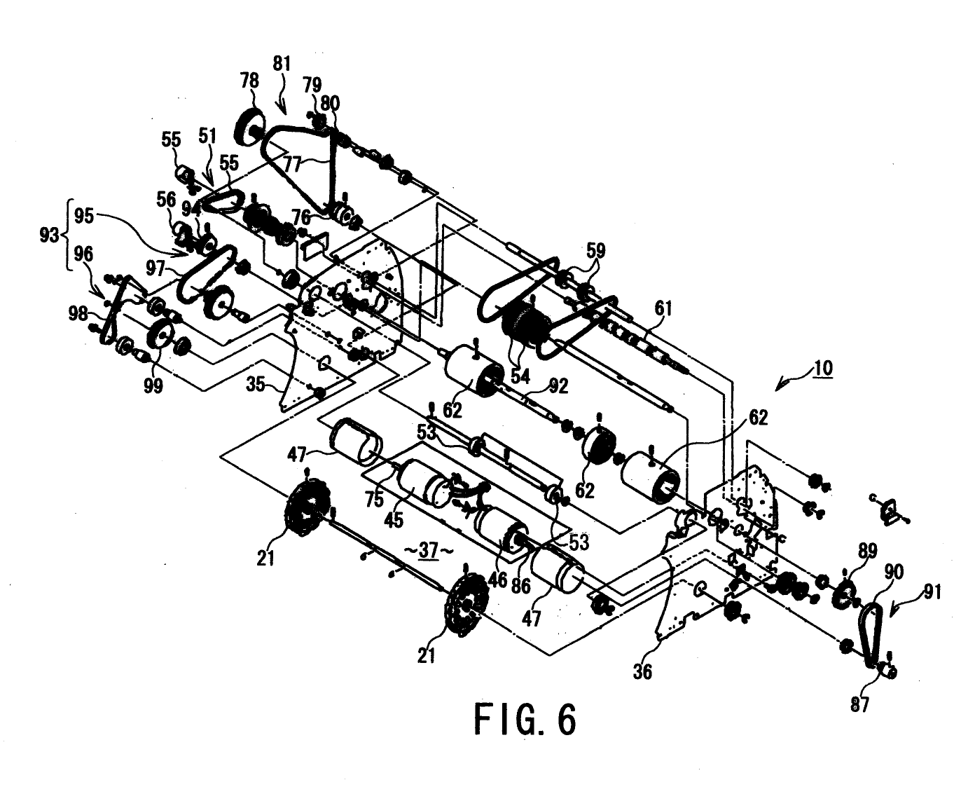

Almost all the various types of the sensors of the bank note identifying/counting apparatus 10 are disposed to the downward linear transport path 52b of the U-shaped or C-shaped transport path 52 as shown in FIG. 6. The hopper sensor 50 is disposed to the hopper 15 in the top portion of the counting apparatus main body 11, and further, a transmission stacker sensor 72 composed of a light transmission element and a light reception element is disposed to the stacker 20 in confrontation with each other by being separated to a light transmission side and a light reception side.

Incidentally, the bank note identifying/counting apparatus 10 is a desktop one-stacker bank note identifying/counting apparatus provided with a continuous feed-out and transport mechanism for continuously feeding out the bank notes 14 stacked on the hopper 15. The bank note identifying/counting apparatus 10 has established a technology for smoothly and continuously feeding out bank noted as paper sheets. The bank note identifying/counting apparatus 10 identifies and counts bank notes after it is applied with an increased speed feed action while the bank notes are being fed so that the bank note identifying/counting apparatus 10 is not adversely affected by the continuous feed-out mechanism. The feed-in rollers 53 and the feed-out roller 54 are in contact with the lowermost surface of a stacked bank note (paper sheet) at all times so that the entire outer peripheral surfaces of the respective rollers contribute to a bank note feed action. As a result, since the number of revolutions of the rollers used in the feed-out mechanism can be reduced as compared with that of a conventional intermittent feed-out mechanism, transport noise can be reduced.

Further, in the bank note identifying/counting apparatus 10, the positions where the various identification sensors are disposed are devised from the view point of an identification accuracy and a maintenance property to keep a high transport performance to the continuous feed-out and transport mechanism and further the slant transport is performed less frequently so that bank notes can be securely and accurately identified and counted.

In the bank note identifying/counting apparatus 10, the bar-shaped magnetic sensor 66, which traverses the downward linear transport path 52b, is installed at a position which is not affected by the increase of speed of bank notes (paper sheets), i.e., upstream of the linear transport path 52b.

Since the magnetic (MG) sensor 66 is installed upstream of the linear transport path 52b, it is not necessary to install an MG sensor to the downstream side transport path 52c after the speed is increased and stabilized. Accordingly, since the transport path can be shortened after the speed is increased, an increase of the size of the bank note identifying/counting apparatus 10 can be prevented. The magnetic sensor 66 is disposed making use of the upstream side, which is a dead space, of the downward linear transport path 52b and further is provided with an openable rear guide 73.

Since the magnetic sensor 66 is disposed to the downward linear transport path 52b and is provided with the rear guide 73 also acting as a release guide, a jam phenomenon can be easily eliminated by opening the back surface side of the bank note identifying/counting apparatus 10 by the rear guide (guide plate) 73.

The magnetic sensor 66 is refrained from being disposed to the transport path after the speed is increased and stabilized and is disposed upstream of the linear transport path 52b to keep the machine size of the desktop compact bank note identifying/counting apparatus 10. Even if the magnetic sensor 66 is disposed at the position, magnetic patterns can be accurately detected by employing a method of scanning the magnetic patterns by switching an encoder signal as a scan reference before the speed is increased and an encoder signal as a scan reference after the speed is increased. When the magnetic sensor is disposed after the speed is increased, the machine size is increased. Thus, to prevent the increase of the machine size, there is employed the arrangement in which the magnetic sensor dares to be disposed on the linear transport path 52b whose speed is increased and the reference signals are switched.

[Drive Path of Bank Note Identifying/Counting Apparatus]

Next, a drive path relation of the bank note identifying/counting apparatus 10 will be explained referring to FIGS. 3 to 6.

As shown in FIG. 6, in the bank note identifying/counting apparatus 10, the feed-out drive motor 45 and the transport drive motor 46 are installed in series right and left on the bottom on the back surface side (rear side) of the main space 37 formed between the right and left main body plates (partition plates) 35, 36. As shown in FIG. 3, a motor shaft 75 of the feed-out drive motor 45 passes through the left side main body plate 35 when viewed from a front surface, and a feed-out side drive pulley 76 is disposed to the projecting portion. A transport path 81 of the paper sheet feed-out drive system 41 is composed of the drive pulley 76 and a timing belt 77 trained around a driven pulley 78 of the feed-in rollers 53, a driven pulley 79 of the intermediate roller 59, and a driven pulley 80 of the flock roller 61.

In contrast, a drive pulley 83 of the feed-in mechanism 51 is disposed to the driven pulley 78 of the feed-in rollers 53 integrally therewith, and the feed-in mechanism 51 is composed of a timing belt 85 trained between the drive pulley 83 and a driven pulley 84 of the feed-out roller 54. In the feed-in mechanism 51, the diameter of the driven pulley 84 is formed larger than that of the drive pulley 83, and they constitute a speed reducing mechanism. The diameter of the feed-out roller 54 of the feed-in mechanism 51 is formed larger than that of the feed-in rollers 53, the feed-out roller 54 and the feed-in rollers 53 are driven in rotation at a required surface speed ratio, and the bank notes 14 stacked on the hopper 15 are sequentially and continuously fed from the lower end thereof and continuously fed out to the U-shaped or C-shaped transport path 52.

At the time, since a friction member such as urethane rubber and the like is disposed around the entire periphery of the feed-out roller 54, even if bank notes to be fed out are continuously fed out, they are fed out with low noise, and since the feed-out roller 54 is continuously in friction contact with the lowermost bank note at all times, uniform feed-out force continuously acts on the lowermost bank notes. As a result, bank notes are stably fed out with low noise without traveling slantly different from a conventional feed-out of bank notes which are fed out intermittently.

In contrast, the transport drive motor 46 is installed as shown in FIG. 6, and a motor shaft 86 thereof is provided with a transport side drive pulley (timing pulley) 87 disposed to the projecting portion of the motor shaft 86 which projects passing through the right main body plate 36 as shown in FIG. 4. A right transport path 91 is composed of the drive pulley 87 and a timing belt 90 trained around the drive pulley 87 and a driven pulley (timing pulley) 89 of the platen roller (speed increasing roller) 62. The transport path 91 reaches a drive pulley 94 of a left transport path 93 disposed to the left side space 38 through a roller shaft 92 of the platen roller 62.

The left transport path 93 constitutes a stacker motor drive path, and the platen roller 62 is driven in rotation as well as a timing belt 97 is driven in rotation by multi-stage drive systems 95, 96.

The platen roller 62 is the speed increasing roller which has the same roller diameter as that of the feed-out roller 54 as shown in FIG. 5 as well as which is driven in rotation at a surface speed of, for example, 1.6 times that of the feed-out roller 54. The numbers of revolutions and the revolution speeds of the platen roller 62 and the feed-out roller 54 are directly and individually detected by the hermetically-sealed rotary encoders 56, 55, respectively.

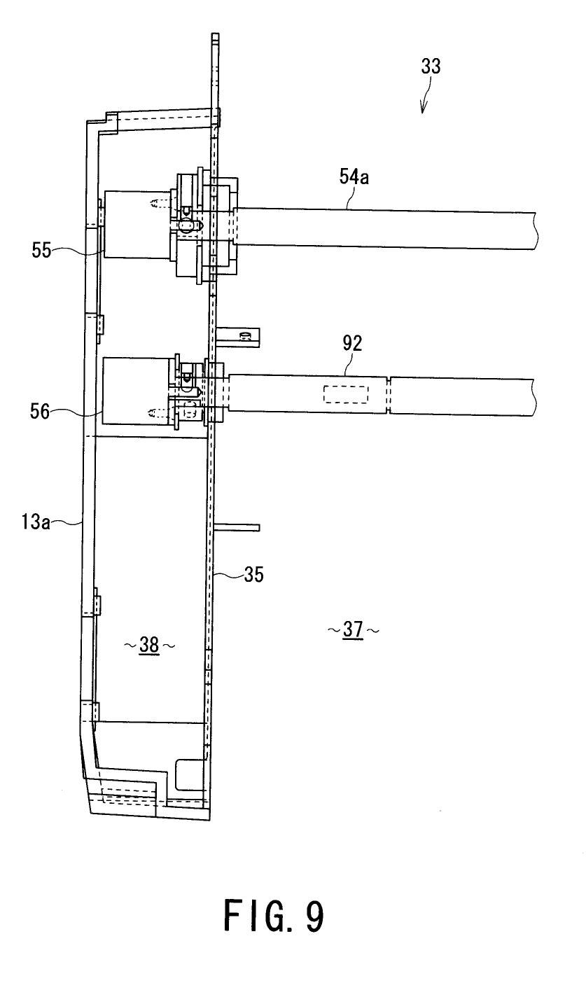

As shown in FIG. 9, since the hermetically-sealed rotary encoders 55, 56 are disposed to the roller shaft ends of the feed-out roller 54 and the platen roller 62, respectively, they can directly detect the number of revolutions and the revolution speeds of the feed-out roller 54 and the platen roller 62. Since variable factors such as the deflection of the belts and the like can be eliminated in addition to the number of revolutions of the rollers and the adverse affect of the speed reducing mechanism, a conversion circuit, and the like, which are disposed in a mid-portion of the motor drive path, can be excluded, the hermetically-sealed rotary encoders 55, 56 can exactly and accurately detect the numbers of revolutions and the surface speeds of the feed-out roller 54 and the platen roller 62.

Further, in the hermetically-sealed rotary encoder 55 attached to the feed-out roller 54 before the bank note speed is increased and the hermetically-sealed rotary encoder 56 attached to the platen roller (speed increasing roller) 62 after the bank note speed is increased, a bank note transport speed before the bank note speed is increased is different from that after the bank note speed is increased. However, since both the rollers 55, 62 have the same roller diameter, a peripheral length per one pulse is the same also with respect to the two different transport speeds with a result that the same measurement reference can be set to a bank note length. Further, since the rotary encoders 55, 56 are of the hermetically-sealed type, they can accurately detect the number of revolutions and the revolution speeds by resolution of, for example, 1 mm or less to 0.5 mm without being adversely affected by dusts such as paper powders and the like, which float, scatter, and are deposited in the bank note identifying/counting apparatus 10, and can stably keep a detection accuracy for a long period.

[Operation of Bank Note Identifying/Counting Apparatus]

The bank note identifying/counting apparatus 10 starts to identify and to count bank notes by turning on the power supply switch 31, operating the operation buttons 61 of the operation panel 16 when necessary in the state that the bank notes to be counted are placed on the hopper 15, selecting a required count mode so that bank notes are counted, different kinds of mixed bank notes are identified and counted, and different kinds of denominations are detected and counted, and depressing a start button.

Bank notes are identified and counted under the control of control equipment and circuit elements such as a control CPU, an arithmetic operation CPU, a program ROM, a controller, and the like of the control substrate (not shown) disposed in the side space 39 between the right side cover 13 and the right main body plate 36 in a floating state.

When the bank note identifying/counting apparatus 10 starts to be operated and the feed-out drive motor 45 and the transport drive motor 46 are driven, the feed-in rollers 53, the feed-out roller 54, the platen roller 62, the stacker vane, and the like of the feed-in mechanism 51 are sequentially driven in rotation.

Whether or not a bank note, which is to be counted by the bank note identifying/counting apparatus 10, exists is detected by the reflection type hopper sensor 50. When the feed-in mechanism 51 is driven, the feed-in rollers 53 and the feed-out roller 54 are driven and the bank notes 14 start to be continuously fed out.

The bank notes 14 stacked on the hopper 15 are sequentially and continuously fed out from a bank note on a lower side by the feed-out roller (drum) 54 and transported to the intermediate roller 59. Subsequently, a bank note clamped by the intermediate roller 59 and the pitch roller 60 is guided from the transport path 52a to the downward linear transport path 52b, travels downward in the linear transport path 52b, and is guided to the platen roller 62 as the speed increasing roller.

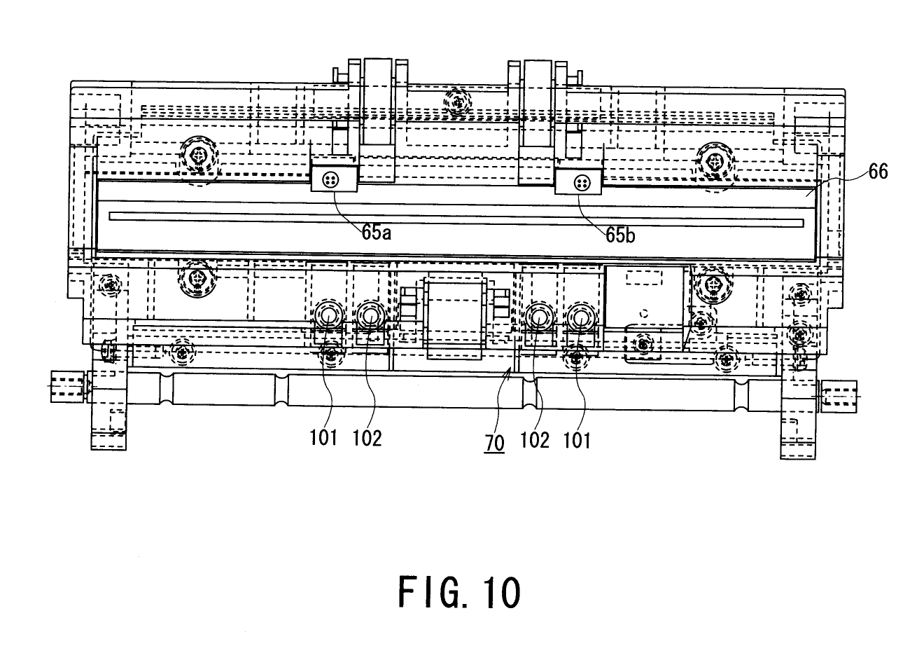

While the bank note is being guided by the downward linear transport path 52, it sequentially passes through magnetic sensor entry sensors 66a, 66b, the magnetic sensor 66, a pair of right and left density sensors 101, and a pair of right and left edge count sensors 102 as shown in FIG. 10. The magnetic sensor 66 has 15 channels (Ch) and a width slightly longer than the longer direction length of a bank note, i.e., a width slightly longer than the transport path width of the linear transport path 52b, for example, a bar-like length of 210 mm to 220 mm. Further, the magnetic sensor entry sensors 66a, 66b detect that a magnetic scan is started and arranged integrally with the magnetic sensor 66 upstream thereof.

Whether or not magnetism exists in the U-shaped or C-shaped transport path 52 is detected by the magnetic sensor 66 disposed upstream of the downward linear transport path 52b. The magnetic sensor 66 detects a magnetic pattern (printed pattern) of magnetic ink and a pattern of a magnetic reaction thread. The magnetic sensor 66 is disposed to the linear transport path 52b at a position at which a bank note is being transported at an increased speed although the bank note is subjected to a speed increasing/changing action at the position so that the length of the transport path 52 of the bank note identifying/counting apparatus 10 is not increased.

Although the transport speed of a bank note before the speed is increased is different from that after the speed is increased, the roller outside diameter of the feed-out roller 54 is set to the same diameter as that of the platen roller 62 so that the same bank note length detection reference can be set even if the transport speeds are different as well as the rotary encoders 55, 56 are directly disposed to the rotor shafts of the respective rollers 54, 62, thereby the detection accuracy is improved. Even if the magnetic sensor 66 is disposed to the downward linear transport path 52b in which the bank note is being transported at the increased speed, the same one magnetic sensor can be used before the speed is increased and after the speed is increased by, switching, for example, the pulses from the two rotary encoders.

Further, the pair of density sensors 101 are disposed right and left downstream of the magnetic sensor 66 to detect the density of transmitted light together with the pair of right and left edge count sensors 102 for detecting entering edges of bank notes and counting the number of them. Both the density sensors 101 and the edge count sensors 102 are transmission type optical sensors. The edge count sensors 102 are edge sensors for accurately detecting the entering edges of bank notes and improving the counting accuracy of the bank notes. Each of the edge count sensors 102 is of a transmission type and composed of a light transmission element 102a and a light reception element 102b. The sensor light receiving element 102b is covered with a pin-hole-like mask so that an edge of a bank note can be detected sharply.

Next, the amount of fluorescence of a bank note is detected by the UV sensor 67 disposed at a position on a central portion side of a bank note (central portion in a longer direction). Subsequently, when the bank notes, which are transported to the linear downward movement transport path, pass through the count sensors 69 located at, for example, two right and left positions in the longer direction, the number of them is detected by count sensors 69. In contrast, the lateral width (longer direction length) and the print pattern of a bank note are detected by the image sensor 68. The paper sheet (bank note) identifying unit 70 is composed of these various types of sensors.

In contrast, when the bank note transported to the linear transport path 52b is pinched by the platen roller 62 and the pinch roller 65, the speed of the bank note being transported is abruptly increased and the bank note is separated from a bank note succeeding to the above preceding bank note. Since a gap is formed between the preceding bank notes and the succeeding bank note, bank notes can be easily counted by the count sensors 69.

When the bank notes being transported is counted, when whether they are true bank notes or counterfeit notes is determined, and when they are identified, the bank notes are transported to the stacker vane 21 passing through the downstream side transport path 52c which slants downward and collected and aligned on the one stacker 20. When the bank notes collected on and accommodated in the stacker 20 reach a preset value, the count of the bank notes is automatically stopped.

The stacker 20 is provided with a transmission type stacker sensor 105, and whether or not the bank notes which are aligned and arranged on the stacker 20 exist is detected by the stacker sensor 105.

[Treatment of Jam Phenomenon of Bank Note Identifying/Counting Apparatus]

Next, maintenance job such as elimination of a jam phenomenon of a bank note and the like in the bank note identifying/counting apparatus 10 will be explained.

When a jam phenomenon occurs to a bank note to be counted in the U-shaped transport path 52 of the bank note identifying/counting apparatus 10 and when the magnetic sensor 66, the density sensor 101, the edge count sensor 102, and the UV sensor 67 are contaminated with paper powders and the like, the rear upper cover 26a of the rear cover 26 is turned about a hinge between it and the rear lower cover 26b and opened as shown in FIG. 7.

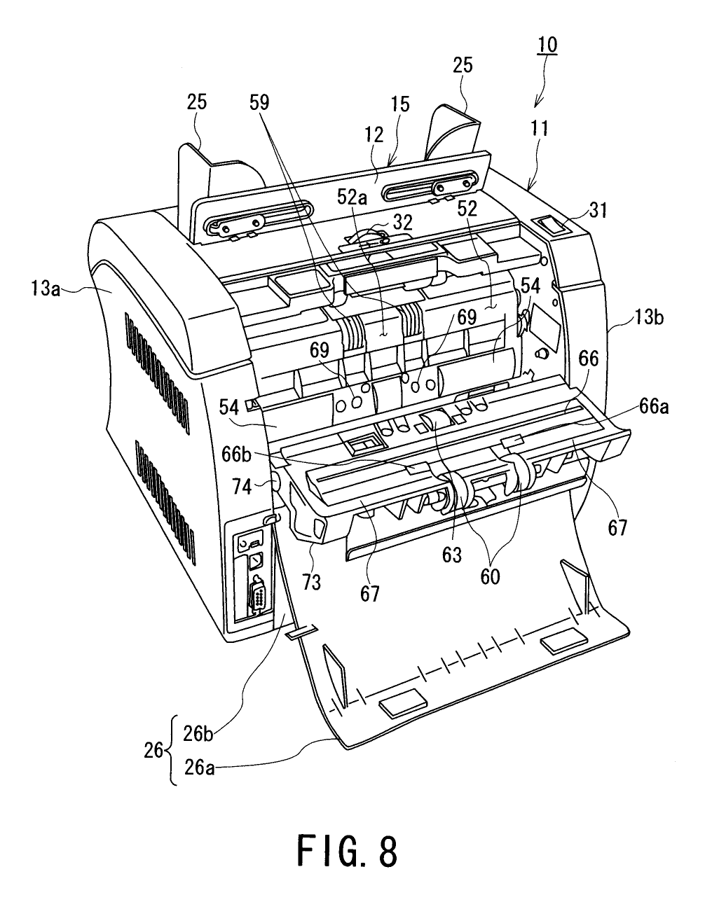

The rear guide 73 is turned about a guide shaft 74 and opened in a state that the rear upper cover 26a is opened. In FIG. 8, when the rear guide 73 is turned clockwise and extended, since the linear transport path 52b of the U-shaped transport path 52 is opened and exposed to the outside, a bank note jammed in the portion can be easily eliminated.

Further, since the magnetic sensor 66, the magnetic sensor entry sensors 66a, 66b, the density sensor 101, and the edge count sensor 102 which are disposed to the rear guide 73 and the count sensors 69 which are disposed between the UV sensor 67 and the platen roller 62 are exposed, the contamination thereof can be eliminated by removing paper powders on the surfaces of the sensors using an accompanying brush, swab, and the like.

Further, since the image sensor 68 is disposed to the transport path 52c and supported by being urged by a spring so that it can be turned, the contamination of the image sensor 68 can be eliminated by removing paper powders on the surface thereof using the accompanying brush, swab, and the like likewise the rear guide 73. Incidentally, a lot of the bank note identifying/counting apparatuses 10 are mainly installed to counters of monetary facilities such as banks and the like. Accordingly, the desktop bank note identifying/counting apparatus 10, which can be handled and operated easily and has a simple and concise structure is more suitable than an expensive bank note identifying/counting apparatus whose handling is complex.

The bank note identifying/counting apparatus 10 is not a complex bank note identifying/counting apparatus having a plurality of pockets (stackers and exclusion pockets) but a small, compact, and simple desktop bank note identifying/counting apparatus which can identify and count bank notes and can detect a counterfeit note.

The bank note identifying/counting apparatus 10 is a desktop identifying/counting apparatus which is suitable for a count process of a bank note bundle in which denominations are mixed, and a first way of use for counting the bank note bundle is to fix the received amount of relatively small amount of money and to check reception of a counterfeit note.

Since a relatively small amount of money is mainly handled, in a process, which is performed in a counter of a monetary facility to count drawn money and deposited money using this type of the bank note identifying/counting apparatus 10, it is preferable to fix the amount of the drawn money and the amount of the deposited money between a customer (user) and a teller in the counter.

In the bank note identifying/counting apparatus 10 of the present invention, when a bank note bundle, which contains bank notes whose denominations are mixed, is counted in a counter of a monetary facility and a discovered counterfeit note and the like exist, a deposit/withdrawal process can be finished after it is visually confirmed between a customer and a teller once, by which the customer is provided with reliability and is given with a good impression as to a job performed in the counter.

The bank note identifying/counting apparatus 10 is arranged to have the one simple transport path structure provided with the one discharge port (stacker) making it unnecessary to provide a complex branch mechanism having a plurality of discharge ports (pockets) each provided with a branch path. The bank note identifying/counting apparatus 10 of the present invention makes the transport path structure simple and concise making it unnecessary to provide a branch transport path branched to the U-shaped or C-shaped transport path 52. Further, when a jam phenomenon occurs to a bank note being transported, since the rear upper cover 26a of the rear cover 26 is turned about the hinge and opened and further the rear guide 73 is turned about a hinge 74 and opened as shown in FIG. 8, the linear transport path 52b of the U-shape transport path 52 is opened to the back side and thus the linear transport path 52b is largely opened.

Since the back side of the linear transport path 52b is opened, a bank note jammed in the path can be simply and easily removed and eliminated. Further, when a bank note being transported is jammed in a portion of the platen roller 62, it can be easily taken out by inserting a hand from a downstream side of the linear transport path 52b opened to the back side to the back side or from a front portion of the stacker vane 21 largely opened upward.

After the bank note to which the jam phenomenon occurs is removed, when the rear guide 73 is returned to its original position, the rear upper cover 26a is closed, and the rear cover 26 is returned to its original position, the bank note identifying/counting apparatus 10 finishes a preparation for a next bank note count process.

1. A paper sheet identifying/counting apparatus comprising:
a hopper to which paper sheets to be identified and counted are supplied;
a paper sheet transport device for continuously feeding out the paper sheets supplied to the hopper and transporting the paper sheets one by one in a shorter direction thereof along a transport path;
a paper sheet identifying unit disposed in a mid-portion of the transport path for identifying and counting the paper sheets; and
one stacker on which the paper sheets fed out from the transport path are stacked,
wherein the transport path is composed of a feed-out transport path to a back side of which the paper sheets from the hopper are continuously fed out, a downward linear transport path succeeding to the feed-out transport path, and a downstream transport path extending forward from the linear transport path to the stacker, and the transport path is formed so as to provide a curved U-shape or C-shape, and
the paper sheet identifying unit is installed upstream of the downward linear transport path so that a magnetic sensor traverses the transport path.

2. The paper sheet identifying/counting apparatus according to claim 1, wherein:
the hopper is formed to a top portion of a counting apparatus main body, and the stacker is formed to a lower portion of the front surface of the counting apparatus main body;
a platen roller is disposed to the transport path curved to the U-shape or C-shape for increasing the speed of the paper sheets transported downstream of the downward linear transport path; and
the platen roller has the same diameter as that of a feed-out roller, and the speed of the platen roller is increased at a required surface speed ratio as compared with the surface speed of the feed-out roller.

3. The paper sheet identifying/counting apparatus according to claim 2, wherein a hermetically sealed rotary encoders are disposed to ends of roller shafts of the feed-out roller and the platen roller, respectively, and the surface speeds or the number of roller revolutions of the feed-out roller and the platen roller are directly detected by the respective rotary encoders.

4. The paper sheet identifying/counting apparatus according to claim 1, wherein:
the paper sheet identifying unit has the magnetic sensor disposed to the downward linear transport path, and the magnetic sensor has a detection width larger than a lateral width of the transport path;
a reflection type approach sensor is disposed upstream of the magnetic sensor integrally therewith for sensing that a magnetic scan is started; and
an edge count sensor, which detects and counts the entering ends of the paper sheets being transported, and a density sensor, which detects the density of transmission light, are disposed right and left in parallel with each other on a downstream side of the magnetic sensor, and the edge count sensor and the density sensor are composed of transmission optical sensors.

5. The paper sheet identifying/counting apparatus according to claim 1, wherein the paper sheet identifying unit is disposed to a rear guide which is free to open and close the downward linear transport path, and a rear cover for covering the rear guide is disposed to the back side of the counting apparatus main body so that it can be freely opened and closed.

6. A paper sheet identifying/counting method, comprising the steps of:
continuously feeding out paper sheets stacked on a hopper to a feed-out transport path at a feed-out speed of 1000 sheets, 1200 sheets, or more per minute;
guiding the fed-out paper sheets to a downward linear transport path;
identifying and counting the paper sheets, and discriminating whether the paper sheets are true or false by a paper sheet identifying unit while the paper sheets pass through the linear transport path;
guiding the paper sheets identified and counted by a paper sheet identifying unit to a downstream transport path; and
feeding out the paper sheets from the downstream transport path to a stacker and stacked on the stacker.

7. The paper sheet identifying/counting method according to claim 6, wherein:
a hermetically-sealed rotary encoder is disposed to a roller shaft of a feed-out roller for continuous feeding out paper sheets to the feed-out transport path for detecting a feed-out speed and the number of revolutions of the roller;
a platen roller for increasing the speed of paper sheets being transported is disposed downstream of the downward linear transport path, and a hermetically-sealed rotary encoder is disposed to a roller shaft of the platen roller to detect an increased speed and the number of revolutions of the roller; and
the feed-out roller and the platen roller which have the same roller diameter are directly detected by the hermetically-sealed rotary encoders so that the detection accuracy of the paper sheets being transported is detected by the same resolution.
